(19) United States
(12) Patent Application Publication
(10) Pub. No.: US 2026/0088208 A1
(43) Pub. Date: Mar. 26, 2026

(54) Filter Circuit Including Parallel Comb-Like Coils

(71) Applicant: Apple Inc., Cupertino, CA (US)

(72) Inventors: Hamidreza Kazemi Varnamkhasti, San Diego, CA (US); Zhengan Yang, Del Mar, CA (US)

(21) Appl. No.: 18/893,536

(22) Filed: Sep. 23, 2024

(51) Int. Cl. H01F 27/28; H01F 27/29; H03H 7/01

(52) U.S. Cl. CPC H01F 27/2804; H01F 27/29; H03H 7/0138

(57) ABSTRACT

This disclosure is generally directed to filters (e.g., band-pass filters) having series resonator circuitry. In particular, this disclosure is directed to filters including multiple cross-coupled comb-like coils forming the series resonator circuitry. The filter may include multiple comb-like coils. The comb-like coils may be cross-coupled, or coupled in parallel, by coupling first terminals of the comb-like coils to each other and coupling second terminals of the comb-like coils to each other. Each comb-like coil may have a respective resonating frequency range. The resonating frequency range of the filter may correspond to a combination of resonating frequency ranges of each of the multiple comb-like coils cross-coupled to each other.

### BACKGROUND

The present disclosure relates generally to filters and electronic devices including filtering circuits.

An electronic system may include one or more filters to attenuate or reduce a magnitude of undesired signals having frequencies outside of a desired frequency range. Filters of the electronic device may have limited resonant frequency, undesired electromagnetic emissions, relatively high resistance and/or inductance with respect to signals with frequencies within the desired frequency range, and/or relatively low resistance with respect to signals with frequencies outside the desired frequency range.

### SUMMARY

This disclosure is generally directed to filters (e.g., band-pass filters) having series resonator circuitry. In particular, this disclosure is directed to filters including multiple cross-coupled comb-like coils forming the series resonator circuitry. A filter may conduct (e.g., nearly pass-through) signals with frequencies within a resonating frequency range and attenuate signals with frequencies outside the resonating frequency range. For example, the filter may reduce a magnitude of at least a portion of noise signals and other undesired signals with frequencies outside the resonating frequency range of the filter.

The filter may include multiple comb-like coils. The comb-like coils may be cross-coupled, or coupled in parallel, by coupling first terminals of the comb-like coils to each other and coupling second terminals of the comb-like coils to each other. Each comb-like coil may have a respective resonating frequency range. The resonating frequency range of the filter may correspond to a combination of resonating frequency ranges of each of the multiple comb-like coils cross-coupled to each other.

In some cases, two or more of the comb-like coils may have a different resonating frequency range. For example, such comb-like coils may have overlapping or non-overlapping resonating frequency ranges. As such, the filter may have a widened resonating frequency range based on including multiple comb-like coils cross-coupled to each other. In specific cases, the comb-like coils may be cross-coupled such that electromagnetic emissions of at least a portion of the comb-like coils may be in opposite (e.g., nearly opposite) directions when receiving signals. As such, the filter may have a reduced electromagnetic emission compared to other filters including comb-like coils.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a front view of a handheld device representing an example of the electronic device of FIG. 1, according to embodiments of the present disclosure;

FIG. 3 is a front view of another handheld device representing another example of the electronic device of FIG. 1, according to embodiments of the present disclosure;

FIG. 4 is a perspective view of a notebook computer representing an example of the electronic device of FIG. 1, according to embodiments of the present disclosure;

FIG. 5 illustrates front and side views of a wearable electronic device representing another example of the electronic device of FIG. 1, according to embodiments of the present disclosure;

FIG. 6 illustrates a layer of a first comb-like coil with non-overlapping parallel traces, according to embodiments of the present disclosure;

FIG. 7 is a cross-sectional view of the first comb-like coil of FIG. 6 including multiple layers, according to embodiments of the present disclosure;

FIG. 8 illustrates a layer of a second comb-like coil with overlapping parallel traces, according to embodiments of the present disclosure;

FIG. 9 is a cross-sectional view of the second comb-like coil of FIG. 8 including multiple layers, according to embodiments of the present disclosure;

FIG. 10 illustrates a first filter of the electronic device of FIGS. 1-5 including two cross-coupled comb-like coils of FIGS. 6-9, according to embodiments of the present disclosure;

FIG. 11 illustrates a second filter of the electronic device of FIGS. 1-5 including four cross-coupled comb-like coils of FIGS. 6-9, according to embodiments of the present disclosure; and

FIG. 12 illustrates a third filter of the electronic device of FIGS. 1-5 including multiple first filters of FIG. 10 and/or second filters of FIG. 11, according to embodiments of the present disclosure, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “including” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1 % of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member or a set may include multiple members. Furthermore, the term “continuous” may correspond to an activity that occurs without interruption or a consecutive repetition with a relatively short time period therebetween.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

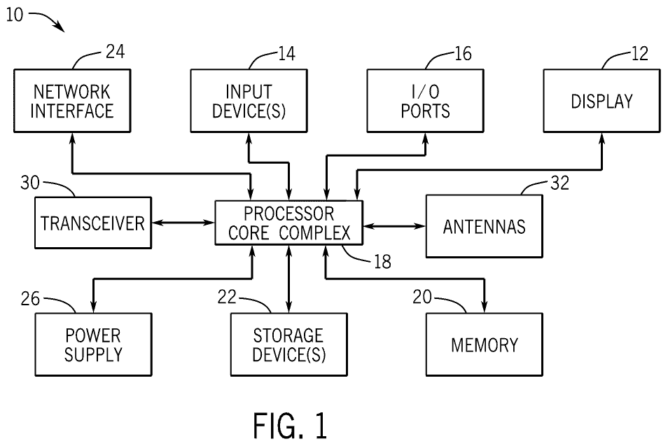

FIG. 1 is a block diagram of an electronic device 10 according to embodiments of the present disclosure. As is described in more detail below, the electronic device 10 may be any suitable electronic device, such as a computer, a mobile phone, a portable media device, a tablet, a television, a virtual-reality headset, a wearable device such as a watch, a vehicle dashboard, or the like. Thus, it should be noted that FIG. 1 is merely one example of a particular implementation and is intended to illustrate the types of components that may be present in an electronic device 10.

The electronic device 10 may include an electronic display 12, one or more input devices 14, one or more input/output (I/O) ports 16, a processor core complex 18 having one or more processing circuitry(s) or processing circuitry cores, local memory 20, a main memory storage device 22, a network interface 24, a power source 26 (e.g., power supply), transceiver 30, and one or more antennas 32. The various components described in FIG. 1 may include hardware elements (e.g., circuitry), software elements (e.g., a tangible, non-transitory computer-readable medium storing executable instructions), or a combination of both hardware and software elements. It should be noted that the various depicted components may be combined into fewer components or separated into additional components. For example, the local memory 20 and the main memory storage device 22 may be included in a single component.

The processor core complex 18 is operably coupled with local memory 20 and the main memory storage device 22. Thus, the processor core complex 18 may execute instructions stored in local memory 20 and/or the main memory storage device 22 to perform operations, such as generating or transmitting image data to display on the electronic display 12. As such, the processor core complex 18 may include one or more processors, one or more general purpose microprocessors, one or more application specific integrated circuits (ASICs), one or more field programmable gate arrays (FPGAs), or any combination thereof. In some embodiments, a system on a chip (SoC) may include the processor core complex 18, among other things.

In addition to program instructions, the local memory 20 or the main memory storage device 22 may store data to be processed by the processor core complex 18. Thus, the local memory 20 and/or the main memory storage device 22 may include one or more tangible, non-transitory, computer-readable media. For example, the local memory 20 may include random access memory (RAM) and the main memory storage device 22 may include read-only memory (ROM), rewritable non-volatile memory such as flash memory, hard drives, optical discs, or the like.

The network interface 24 may communicate data with another electronic device or a network. For example, the network interface 24 (e.g., a radio frequency system) may enable the electronic device 10 to communicatively couple to a personal area network (PAN), such as a Bluetooth network, a local area network (LAN), such as an 802.11x Wi-Fi network, or a wide area network (WAN), such as a 4G, Long-Term Evolution (LTE), or 5G cellular network.

The power source 26 may provide electrical power to the electronic display 12, the input devices 14, the I/O ports 16, the processor core complex 18, the local memory 20, the main memory storage device 22, the network interface 24, the power source 26, the transceiver 30, or a combination thereof, among other things. The power source 26 may include any suitable source of energy, such as a rechargeable lithium polymer (Li-poly) battery or an alternating current (AC) power converter.

The transceiver 30 may include transmitters and receivers coupled via communication buses to transmit and receive data. In some embodiments, the transceiver 30 may include circuitry for data communication using any version of a serializer and deserializer (SerDes) interface, a peripheral component interconnect express (PCIe) interface, or any other viable interfacing protocol, such as various communication standards. It should be appreciated that the transceiver 30 may include and/or utilize any viable circuitry to facilitate data communication between multiple circuits, components, chips, integrated circuits (ICs), and so on. For example, the transceiver 30 may be coupled to a first chip and a second chip to provide a chip-to-chip (C2C) interface. Moreover, it should be appreciated that the primary circuit and the secondary circuit of the transceiver 30 may communicate via a wired link (e.g., a bus) or a wireless link. For example, the transceiver 30 may use any viable communication protocol, such as Wi-Fi, 4G LTE, or 5G NR, among other possibilities, to establish and communicate using the wireless link.

The I/O ports 16 may enable the electronic device 10 to interface with other electronic devices. For example, when a portable storage device is connected, the I/O port 16 may enable the processor core complex 18 to communicate data with the portable storage device. The input devices 14 may enable user interaction with the electronic device 10, for example, by receiving user inputs via a button, a keyboard, a mouse, a trackpad, or the like. The input device 14 may include touch-sensing components in the electronic display 12. The touch sensing components may receive user inputs by detecting occurrence or position of an object touching the surface of the electronic display 12.

The electronic display 12 may include driver circuitry (e.g., display driver circuitry) and/or a display panel. The electronic device 10 may also have the one or more antennas 32 electrically coupled to the processor core complex 18. The electronic device 10 may be any suitable electronic device.

With the foregoing in mind, the electronic device 10 may include one or more filters (e.g., band-pass filters) to reduce a magnitude of noise signals, undesired electromagnetic emissions, and/or other undesired signals of the electronic device 10. For example, the electronic display 12, the input devices 14, the I/O ports 16, the processor core complex 18, the local memory 20, the main memory storage device 22, the network interface 24, the power source 26 (e.g., power supply), the transceiver 30, the antennas 32, or a combination thereof, among other components of the electronic device 10, may each include and/or be coupled to one or more filters. In a non-limiting example, a filter may be coupled to an output terminal of a clock circuit of the electronic device 10 to reduce at least a portion of noise signals of the clock circuit.

A filter may conduct (e.g., pass through) signals with frequencies within a resonating frequency range and reduce a magnitude of signals with frequencies outside the resonating frequency range. For example, the noise signals, the undesired electromagnetic emissions, and/or the other undesired signals of the electronic device 10 may have frequencies outside the resonating frequency range.

The filter may include multiple cross-coupled comb-like coils. Each of the cross-coupled comb-like coils may have a respective resonating frequency range. A resonating frequency range of the filter may correspond to the resonating frequency ranges of each of the comb-like coils. Moreover, two or more of the comb-like coils may have a different resonating frequency range. As such, the filter may have a widened resonating frequency range based on including multiple comb-like coils cross-coupled to each other.

In some embodiments, the filter may have an increased resonating frequency range compared to other filters with the same or nearly the same footprint. That is, the filter may have an increased resonating frequency range based on including multiple comb-like coils cross-coupled to each other. In some cases, the multiple cross-coupled comb-like coils may provide a lower resistance and/or inductance to signals with frequencies within the resonating frequency range compared to other filters, for example, having comb-like coils. Alternatively or additionally, the multiple cross-coupled comb-like coils may provide a higher resistance and/or inductance to signals with frequencies outside the resonating frequency range compared to other filters. As such, the filter may have improved efficiency and signal quality compared to other filters.

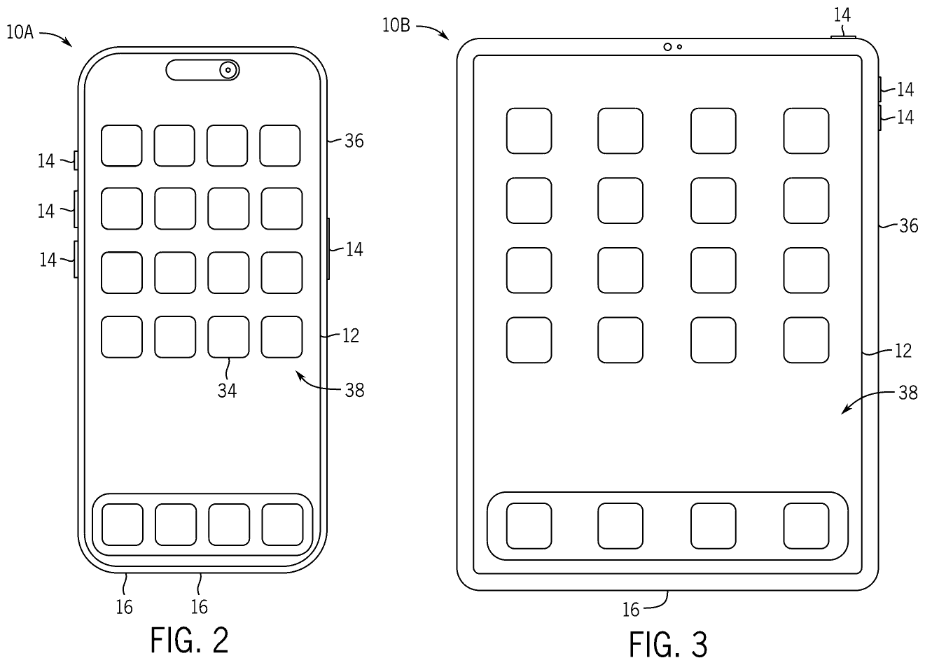

An example of the electronic device 10, a handheld device 10A, is shown in FIG. 2. The handheld device 10A may be a portable phone, a media player, a personal data organizer, a handheld game platform, or the like. For illustrative purposes, the handheld device 10A may be a smart phone, such as an IPHONE® model available from Apple Inc.

The handheld device 10A includes an enclosure 36 (e.g., housing). The enclosure 36 may protect interior components from physical damage or shield them from electromagnetic interference, such as by surrounding the electronic display 12. The electronic display 12 may display a graphical user interface (GUI) 38 having an array of icons. When an icon 34 is selected either by an input device 14 or a touch-sensing component of the electronic display 12, an application program may launch.

The input devices 14 may be accessed through openings in the enclosure 36. The input devices 14 may enable a user to interact with the handheld device 10A. For example, the input devices 14 may enable the user to activate or deactivate the handheld device 10A, navigate a user interface to a home screen, navigate a user interface to a user-configurable application screen, activate a voice-recognition feature, provide volume control, or toggle between vibrate and ring modes.

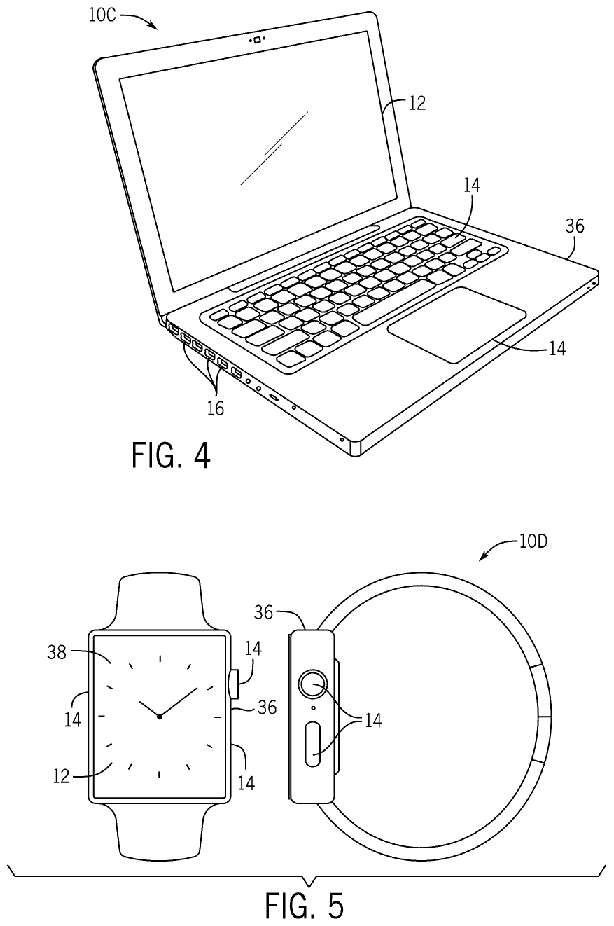

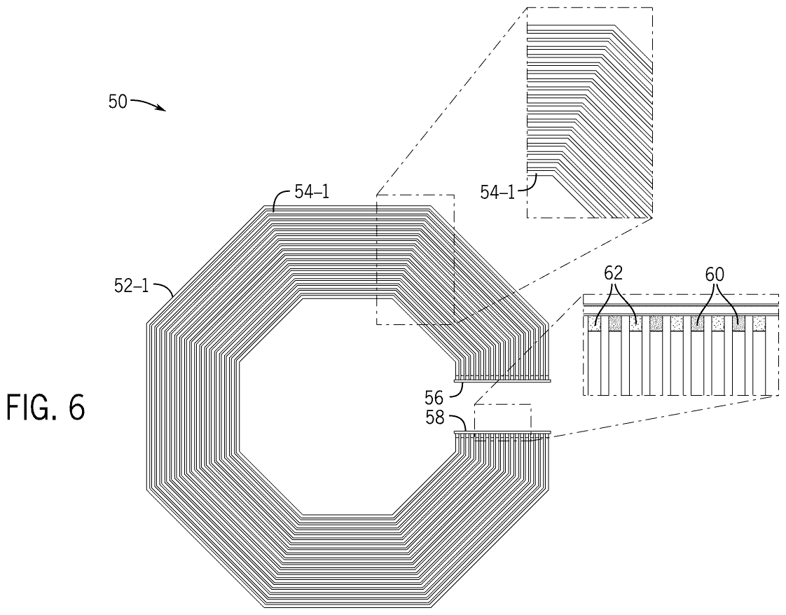

Another example of a suitable electronic device 10, specifically a tablet device 10B, is shown in FIG. 3. The tablet device 10B may be an IPAD® model available from Apple Inc. A further example of a suitable electronic device 10, specifically a computer 10C, is shown in FIG. 4. For illustrative purposes, the computer 10C may be a MACBOOK® or IMAC® model available from Apple Inc. Another example of a suitable electronic device 10, specifically a watch 10D, is shown in FIG. 5. For illustrative purposes, the watch 10D may be an APPLE WATCH® model available from Apple Inc. As depicted, the tablet device 10B, the computer 10C, and the watch 10D each also includes an electronic display 12, input devices 14, I/O ports 16, and an enclosure 36. The electronic display 12 may display a GUI 38.

FIG. 6 illustrates a first layer 52-1 of a comb-like coil 50 with non-overlapping parallel (e.g., comb-like) traces 54-1, according to embodiments of the present disclosure. Although a first layer 52-1 of the comb-like coil 50 is shown in FIG. 6, it should be appreciated that in alternative or additional embodiments, the comb-like coil 50 may include a different number (e.g., N, 2, 3, 4, and so on) of layers. In some embodiments, the first layer 52-1 may be disposed on a first plane surface (e.g., a first circuit layer), for example, of a printed circuit board (PCB), among other possibilities.

In different embodiments, the first layer 52-1 may include a different number of traces 54-1. The traces 54-1 may be disposed adjacently and in parallel. In some cases, the traces 54-1 may be disposed concentrically (e.g., approximately concentrically) around each other. For example, the traces 54-1 may share a same center. In the depicted embodiment, the traces 54-1 may have an octagonal shape. It should be appreciated that in different embodiments, the traces 54-1 of the first layer 52-1 may form a circular shape or a different polygonal shape with different number of sides and/or side lengths.

The comb-like coil 50 may include a first terminal 56 and a second terminal 58. In some embodiments, the comb-like coil 50 may couple to one or more components of the electronic device 10 of FIGS. 1-5 discussed above via the first terminal 56 and the second terminal 58. The comb-like coil 50 may receive signals via the first terminal 56 (or the second terminal 58) and may output signals (e.g., filtered signals) via the second terminal 58 (or the first terminal 56). Every other trace 54-1 is connected to the first terminal 56, with the intervening traces 54-1 being connected to the second terminal 58. That is, adjacent traces 54-1 of the first layer 52-1 may be coupled to different terminals (e.g., the first terminal 56 and the second terminal 58) of the comb-like coil 50. In the depicted embodiment, every other trace 54-1 is coupled to the first terminal 56 via a respective coupler 60 and remains uncoupled to the second terminal 58 based on a respective gap 62. Moreover, the intervening traces 54-1 are coupled to the second terminal 58 via respective couplers 60 and remain uncoupled to the first terminal 56 based on respective gaps 62.

The comb-like coil 50 may direct (e.g., conduct, nearly pass-through) signals with frequencies within (e.g., equal to or within) a resonating frequency range through the traces 54-1 of the first layer 52-1. For example, the adjacent traces 54-1 of the first layer 52-1, coupled to the different terminals 56 and 58, may capacitively couple (e.g., short, nearly short) to conduct (e.g., nearly pass-through) signals with frequencies within (e.g., equal to or within) the resonating frequency range. Moreover, the comb-like coil 50 may attenuate (e.g., filter) signals with frequencies outside the resonating frequency range. For example, the adjacent traces 54-1 may capacitively uncouple (e.g., open, nearly open) to attenuate (e.g., nearly block) signals with frequencies outside the resonating frequency range. Accordingly, the comb-like coil 50 may conduct the signals with frequencies within the resonating frequency range while reducing a magnitude of at least a portion of noise signals and other undesired signals with frequencies outside the resonating frequency range.

It should be appreciated that the comb-like coil 50 may have the resonating frequency range based on one or more parameters of the traces 54-1. In different embodiments, the traces 54-1 may be formed from different viable material and may form a circular shape or a polygonal shape with a different number of sides (e.g., 3, 4, 5, and so on) associated with the resonating frequency range. Moreover, each of the traces 54-1 may have lengths, widths, and/or height associated with the resonating frequency range. Furthermore, spacings between the traces 54-1 of the first layer 52-1 may be associated with the resonating frequency range. As such, the traces 54-1 may have the resonating frequency range based on spacings and/or the material, shape, lengths, widths, and/or height of the traces 54-1, among other possibilities.

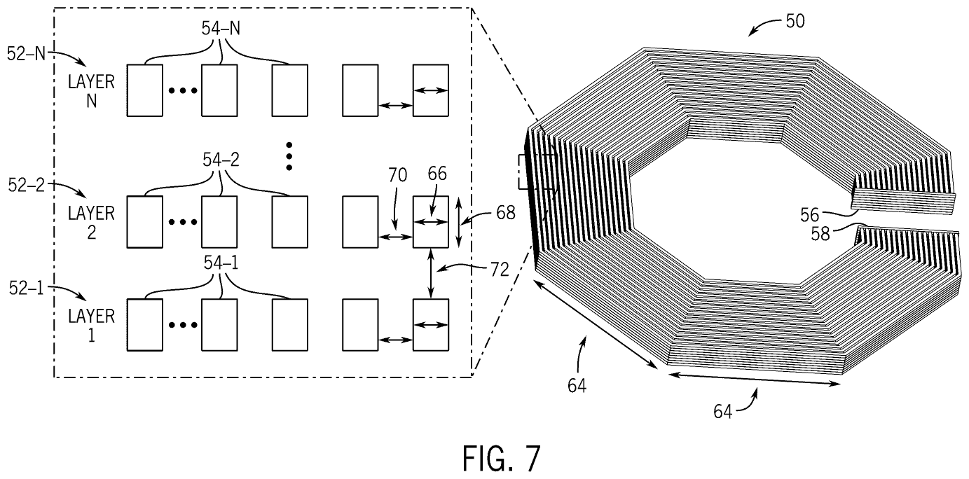

FIG. 7 is a cross-section view of the comb-like coil 50 including multiple layers 52-1, 52-2, and 52-N, according to embodiments of the present disclosure. Each of the layers 52-1, 52-2, and 52-N may include respective non-overlapping parallel (e.g., comb-like) traces 54-1, 54-2, and 54-N. In different embodiments, the comb-like coil 50 may include a different number (e.g., N, 1, 2, 3, 4, and so on) of layers 52-1, 52-2, and 52-N. In some embodiments, each of the layers 52-1, 52-2, and 52-N may be overlaid on adjacent plane surfaces in parallel. For example, each of the layers 52-1, 52-2, and 52-N may be disposed on different plane surfaces of the PCB, among other possibilities.

Each of the layers 52-1, 52-2, and 52-N may include a number of respective traces 54-1, 54-2, and 54-N disposed in parallel. Moreover, each of the traces 54-1, 54-2, and 54-N of each layer 52-1, 52-2, and 52-N may be overlaid. For example, each of the traces 54-1, 54-2, and 54-N of each layer 52-1, 52-2, and 52-N may be disposed parallel and adjacent to (e.g., in proximity of) a respective trace 54-1, 54-2, and 54-N of a neighboring layer 52-1, 52-2, and 52-N. In some embodiments, the traces 54-1, 54-2, and 54-N of each layer 52-1, 52-2, and 52-N may be disposed concentrically (e.g., approximately concentrically) around each other. For example, the traces 54-1, 54-2, and 54-N may share a same center. In the depicted embodiment, the traces 54-1, 54-2, and 54-N may each have an octagonal shape. It should be appreciated that in different embodiments, each of the traces 54-1, 54-2, and 54-N may form a circular shape or a different polygonal shape with different numbers of sides and/or side lengths.

As mentioned above, the comb-like coil 50 may include the first terminal 56 and the second terminal 58. Every other trace 54-1, 54-2, and 54-N of each layer 52-1, 52-2, and 52-N is connected to the first terminal 56, with the intervening traces 54-1, 54-2, and 54-N of the respective layer 52-1, 52-2, and 52-N being connected to the second terminal 58. As such, adjacent traces 54-1, 54-2, and 54-N of (e.g., within) each layer 52-1, 52-2, and 52-N may be coupled to different terminals (e.g., the first terminal 56 and the second terminal 58). Moreover, adjacent traces 54-1, 54-2, and 54-N of neighboring layers 52-1, 52-2, and 52-N may be coupled to different terminals of the comb-like coil 50. For example, a first trace 54-1 of the first layer 52-1 may be coupled to the first terminal 56 while a second trace 54-1 disposed adjacent to the first trace 54-1 within the first layer 52-1 and a first trace 54-2 disposed adjacent to the first trace 54-1 on a neighboring second layer 52-2 may be coupled to the second terminal 58.

The comb-like coil 50 may direct (e.g., conduct, nearly pass-through) signals with frequencies within (e.g., equal to or within) the resonating frequency range through the traces 54-1, 54-2, and 54-N of each layer 52-1, 52-2, and 52-N. For example, the adjacent traces 54-1, 54-2, and 54-N of (e.g., within) each layer 52-1, 52-2, and 52-N, coupled to the different terminals 56 and 58, may capacitively couple (e.g., short, nearly short) to conduct signals with frequencies within the resonating frequency range. Moreover, the adjacent traces 54-1, 54-2, and 54-N of neighboring layers 52-1, 52-2, and 52-N, coupled to the different terminals 56 and 58, may capacitively couple across the layers 52-1, 52-2, and 52-N to conduct signals with frequencies within the resonating frequency range. Accordingly, the comb-like coil 50 may direct the signals with frequencies within the resonating frequency range through the traces 54-1, 54-2, and 54-N of each of the respective layers 52-1, 52-2, and 52-N that are disposed adjacently and/or overlaid along multiple plane surfaces.

The comb-like coil 50 may attenuate signals with frequencies outside the resonating frequency range. For example, the adjacent traces 54-1, 54-2, and 54-N of each layer 52-1, 52-2, and 52-N may capacitively uncouple (e.g., open, nearly open) to attenuate (e.g., nearly block) signals with frequencies outside the resonating frequency range. Moreover, the adjacent traces 54-1, 54-2, and 54-N of neighboring layers 52-1, 52-2, and 52-N, coupled to the different terminals 56 and 58, may capacitively uncouple (e.g., open, nearly open) to attenuate (e.g., nearly block) signals with frequencies outside the resonating frequency range. Accordingly, the comb-like coil 50 may conduct the signals with frequencies within the resonating frequency range while reducing a magnitude of at least a portion of noise signals and other undesired signals with frequencies outside the resonating frequency range.

It should be appreciated that the comb-like coil 50 may have the resonating frequency range based on one or more parameters of the traces 54-1, 54-2, and 54-N. In different embodiments, each of the traces 54-1, 54-2, and 54-N may be formed from different viable material and may form a circular shape or a polygonal shape with a different number of sides (e.g., 3, 4, 5, and so on) associated with the resonating frequency range. Moreover, each of the traces 54-1, 54-2, and 54-N may have side lengths 64, widths 66, and/or heights 68 associated with the resonating frequency range. Furthermore, spacings 70 between the traces 54-1, 54-2, and 54-N of each layer 52-1, 52-2, and 52-N and spacings 72 between adjacent traces 54-1, 54-2, and 54-N of neighboring layer 52-1, 52-2, and 52-N may be associated with the resonating frequency range. As such, the traces 54-1, 54-2, and 54-N may have the resonating frequency range based on spacings 70 and 72 and/or the material, shape, lengths 64, widths 66, and/or height 68 of the traces 54-1, 54-2, and 54-N, among other possibilities.

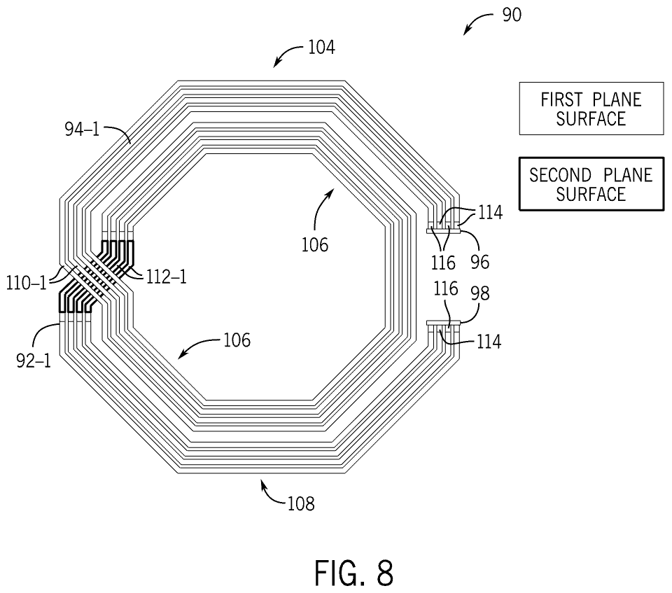

FIG. 8 illustrates a first layer 92-1 of a comb-like coil 90 with overlapping parallel (e.g., comb-like) traces 94-1, according to embodiments of the present disclosure. Although a first layer 92-1 with intertwined (e.g., overlapping) traces 94-1 is shown in FIG. 8, it should be appreciated that in alternative or additional embodiments, the comb-like coil 90 may include a different number (e.g., N, 2, 3, 4, and so on) of layers having intertwined traces. In some embodiments, the first layer 92-1 may be disposed on a first plane surface (e.g., a first circuit layer) and a second plane surface (e.g., a second circuit layer), for example, of a PCB, among other possibilities.

In different embodiments, the first layer 92-1 may include a different number of traces 94-1. The traces 94-1 may be disposed adjacently and in parallel. In some cases, the traces 94-1 may be disposed concentrically (e.g., approximately concentrically) around each other. For example, the traces 94-1 may share the same or approximately the same center. The comb-like coil 90 may include a first terminal 96 and a second terminal 98. In some embodiments, the traces 94-1 may couple to one or more components of the electronic device 10 of FIGS. 1-5 discussed above via the first terminal 96 and the second terminal 98.

The traces 94-1 may each include a first outer section 104, an inner section 106, a second outer section 108, a first connector 110-1, and a second connector 112-1. In the depicted embodiment, the outer sections 104 and 108 may form portions of an octagonal shape of the first layer 92-1. For example, the first outer section 104 may be disposed at least partially symmetrical to the second outer section 108. It should be appreciated that in different embodiments, the outer sections 104 and 108 may form a circular shape or a different polygonal shape with different number of sides and/or side lengths.

Moreover, the inner section 106 and the outer sections 104 and 108 may be interwoven or intertwined with one another. In the depicted embodiment, the inner section 106 may form an octagonal shape concentrically (e.g., approximately sharing a same center) or eccentrically (e.g., not sharing a same center) inside an area between the outer sections 104 and 108. In different embodiments, the inner section 106 may form a circular shape or different polygonal shapes. In some embodiments, the inner section 106 and the outer sections 104 and 108 do not overlap. It should be appreciated that in alternative or additional embodiments, at least a portion of the inner section 106 may overlap with the outer section 104 and/or 108.

The first outer section 104 of each trace 94-1 may be coupled to the first terminal 96. The second outer section 108 of each trace 94-1 may be coupled to the second terminal 98. The first outer section 104 of each trace 94-1 may be coupled to the inner section 106 of the trace 94-1 via a first connector 110-1. The inner section 106 of each trace 94-1 may be coupled to the second outer section 108 of the trace 96-1 via a second connector 112-1. The traces 94-1 may overlap based on the second connectors 112-1 crossing under (or over) the first connectors 110-1. For example, the sections 104, 106, and 108 and the first connectors 110-1 may be disposed on the first plane surface and the second connectors 112-1 may be disposed on the second plane surface.

The comb-like coil 90 may receive signals via the first terminal 96 (or the second terminal 98) and may output signals (e.g., filtered signals) via the second terminal 98 (or the first terminal 96). Every other trace 94-1 is connected to the first terminal 96, with the intervening traces 94-1 being connected to the second terminal 98. That is, adjacent traces 94-1 of the first layer 92-1 may be coupled to different terminals (e.g., the first terminal 96 and the second terminal 98) of the comb-like coil 90. In the depicted embodiment, every other trace 94-1 is coupled to the first terminal 96 via a respective coupler 114 and remains uncoupled to the second terminal 98 based on a respective gap 116. Moreover, the intervening traces 94-1 are coupled to the second terminal 98 via respective couplers 114 and remain uncoupled to the first terminal 96 based on respective gaps 116.

The comb-like coil 90 may direct (e.g., conduct, nearly pass-through) signals with frequencies within (e.g., equal to or within) the resonating frequency range through the traces 94-1 of the first layer 92-1. For example, the adjacent traces 94-1 of the first layer 92-1, coupled to the different terminals 96 and 98, may capacitively couple (e.g., short, nearly short) to conduct (e.g., nearly pass-through) signals with frequencies within (e.g., equal to or within) the resonating frequency range. Moreover, the comb-like coil 90 may attenuate signals with frequencies outside the resonating frequency range. For example, the adjacent traces 94-1 may capacitively uncouple (e.g., open, nearly open) to attenuate (e.g., nearly block) signals with frequencies outside the resonating frequency range. Accordingly, the comb-like coil 90 may conduct the signals with frequencies within the resonating frequency range while reducing a magnitude of at least a portion of noise signals and other undesired signals with frequencies outside the resonating frequency range.

It should be appreciated that the comb-like coil 90 may have the resonating frequency range based on one or more parameters of the traces 94-1. In different embodiments, the traces 94-1 may be formed from different viable material and may form a circular shape or a polygonal shape with a different number of sides (e.g., 3, 4, 5, and so on) associated with the resonating frequency range. Moreover, each of the traces 94-1 may have lengths, widths, and/or height associated with the resonating frequency range. Furthermore, spacings between the traces 94-1 of the first layer 92-1 may be associated with the resonating frequency range. As such, the traces 94-1 may have the resonating frequency range based on spacings and/or the material, shape, lengths, widths, and/or height of the traces 94-1, among other possibilities.

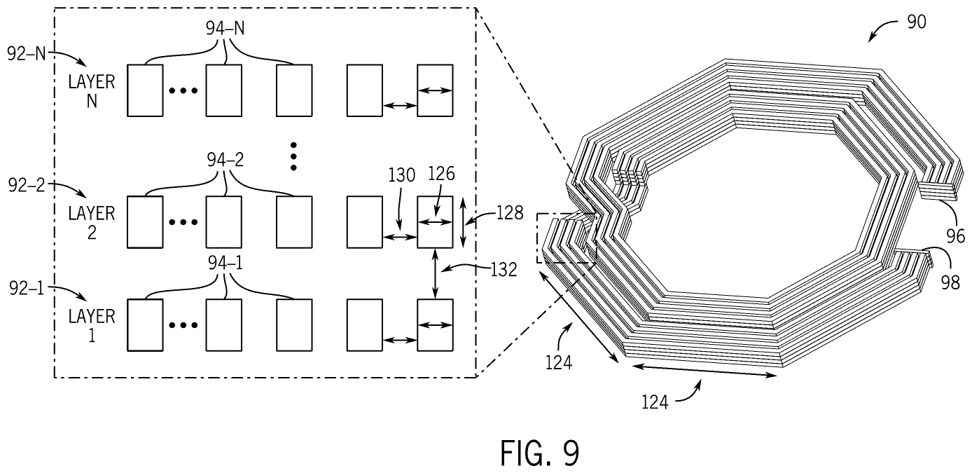

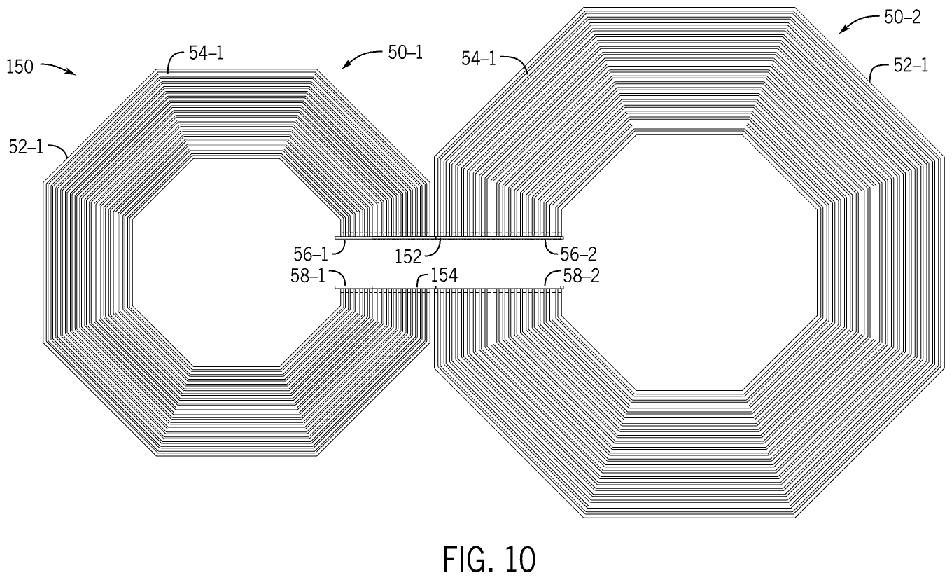

FIG. 9 is a cross-section view of the comb-like coil 90 including multiple layers 92-1, 92-2, and 92-N, according to embodiments of the present disclosure. Each of the layers 92-1, 92-2, and 92-N may include respective overlapping and parallel (e.g., comb-like) traces 94-1, 94-2, and 94-N. In different embodiments, the comb-like coil 90 may include a different number (e.g., N, 1, 2, 3, 4, and so on) of layers 92-1, 92-2, and 92-N. In some embodiments, each of the layers 92-1, 92-2, and 92-N may be overlaid on adjacent plane surfaces in parallel. For example, each of the layers 92-1, 92-2, and 92-N may be disposed on different plane surfaces of the PCB, among other possibilities.

Each of the layers 92-1, 92-2, and 92-N may include a number of respective traces 94-1, 94-2, and 94-N disposed in parallel. Moreover, each of the traces 94-1, 94-2, and 94-N of each layer 92-1, 92-2, and 92-N may be overlaid. For example, each of the traces 94-1, 94-2, and 94-N of each layer 92-1, 92-2, and 92-N may be disposed parallel and adjacent to (e.g., in proximity of) a respective trace 94-1, 94-2, and 94-N of a neighboring layer 92-1, 92-2, and 92-N. In some embodiments, the traces 94-1, 94-2, and 94-N of each layer 92-1, 92-2, and 92-N may be disposed concentrically (e.g., approximately concentrically) around each other. For example, the traces 94-1, 94-2, and 94-N may share a same center. In the depicted embodiment, the traces 94-1, 94-2, and 94-N may each have intertwined octagonal shapes. It should be appreciated that in different embodiments, each of the traces 94-1, 94-2, and 94-N may form intertwined circular shapes or intertwined polygonal shapes with different number of sides and/or side lengths.

As mentioned above, the comb-like coil 90 may include the first terminal 96 and the second terminal 98. Every other trace 94-1, 94-2, and 94-N of each layer 92-1, 92-2, and 92-N is connected to the first terminal 96, with the intervening traces 94-1, 94-2, and 94-N of the respective layer 92-1, 92-2, and 92-N being connected to the second terminal 98. As such, adjacent traces 94-1, 94-2, and 94-N of (e.g., within) each layer 92-1, 92-2, and 92-N may be coupled to different terminals (e.g., the first terminal 96 and the second terminal 98). Moreover, adjacent traces 94-1, 94-2, and 94-N of neighboring layers 92-1, 92-2, and 92-N may be coupled to different terminals of the comb-like coil 90. For example, a first trace 94-1 of the first layer 92-1 may be coupled to the first terminal 96 while a second trace 94-1 disposed adjacent to the first trace 94-1 within the first layer 92-1 and a first trace 94-2 disposed adjacent to the first trace 94-1 on a neighboring second layer 92-2 may be coupled to the second terminal 98.

The comb-like coil 90 may direct (e.g., conduct, nearly pass-through) signals with frequencies within (e.g., equal to or within) the resonating frequency range through the traces 94-1, 94-2, and 94-N of each layer 92-1, 92-2, and 92-N. For example, the adjacent traces 94-1, 94-2, and 94-N of (e.g., within) each layer 92-1, 92-2, and 92-N, coupled to the different terminals 96 and 98, may capacitively couple (e.g., short, nearly short) to conduct signals with frequencies within the resonating frequency range. Moreover, the adjacent traces 94-1, 94-2, and 94-N of neighboring layers 92-1, 92-2, and 92-N, coupled to the different terminals 96 and 98, may capacitively couple across the layers 92-1, 92-2, and 92-N to conduct signals with frequencies within the resonating frequency range. Accordingly, the comb-like coil 90 may direct the signals with frequencies within the resonating frequency range through the traces 94-1, 94-2, and 94-N of each of the respective layers 92-1, 92-2, and 92-N that are disposed adjacently and/or overlaid along multiple plane surfaces.

The comb-like coil 90 may attenuate signals with frequencies outside the resonating frequency range. For example, the adjacent traces 94-1, 94-2, and 94-N of each layer 92-1, 92-2, and 92-N may capacitively uncouple (e.g., open, nearly open) to attenuate (e.g., nearly block) signals with frequencies outside the resonating frequency range. Moreover, the adjacent traces 94-1, 94-2, and 94-N of neighboring layers 92-1, 92-2, and 92-N, coupled to the different terminals 96 and 98, may capacitively uncouple (e.g., open, nearly open) to attenuate (e.g., nearly block) signals with frequencies outside the resonating frequency range. Accordingly, the comb-like coil 90 may conduct the signals with frequencies within the resonating frequency range while reducing a magnitude of at least a portion of noise signals and other undesired signals with frequencies outside the resonating frequency range.

It should be appreciated that the comb-like coil 90 may have the resonating frequency range based on one or more parameters of the traces 94-1, 94-2, and 94-N. In different embodiments, each of the traces 94-1, 94-2, and 94-N may be formed from different viable material and may form circular shapes and/or polygonal shapes with different number of sides (e.g., 3, 4, 5, and so on) associated with the resonating frequency range. Moreover, each of the traces 94-1, 94-2, and 94-N may have side lengths 124, widths 126, and/or height 128 associated with the resonating frequency range. Furthermore, spacings 130 between the traces 94-1, 94-2, and 94-N of each layer 92-1, 92-2, and 92-N and spacings 132 between adjacent traces 94-1, 94-2, and 94-N of neighboring layer 92-1, 92-2, and 92-N may be associated with the resonating frequency range. As such, the traces 94-1, 94-2, and 94-N may have the resonating frequency range based on spacings 130 and 132 and/or the material, shape, lengths 124, widths 126, and/or height 128 of the traces 94-1, 94-2, and 94-N, among other possibilities.

FIGS. 10-12 illustrate filters 150, 170, and 190 including multiple comb-like coils 50 to conduct (e.g., pass-through) signals with frequencies within (e.g., equal to or within) a resonating frequency range and attenuate signals with frequencies outside the resonating frequency range. In the depicted embodiments, the filters 150, 170, and 190 of FIGS. 10-12 are discussed with respect to the comb-like coil 50 of FIGS. 6 and/or 7. It should be appreciated that in alternative or additional embodiments, the filters 150, 170, and 190 of FIGS. 10-12 may include one or more of the overlapping or intertwined comb-like coils 90 of FIGS. 8 and/or 9. For example, the filters 150, 170, and/or 190 may each include one or more second comb-like coils 90 to conduct (e.g., pass-through) signals with frequencies within the respective resonating frequency range and attenuate signals with frequencies outside the respective resonating frequency range.

With the foregoing in mind, FIG. 10 illustrates the first filter 150 of the electronic device 10 of FIGS. 1-5 including two cross-coupled comb-like coils 50-1 and 50-2 of FIGS. 6 and 7, according to embodiments of the present disclosure. Although a first layer 52-1 of the comb-like coils 50-1 and 50-2 is shown, it should be appreciated that in alternative or additional embodiments, the comb-like coil 50-1 and/or 50-2 may include a different number (e.g., N, 2, 3, 4, and so on) of layers 52, as described above with respect to FIG. 7. Moreover, as mentioned above, it should be appreciated that in alternative or additional embodiments, the first filter 150 may include two cross-coupled comb-like coils 90-1 and 90-2 of FIGS. 8 and/or 9 or include a comb-like coil 50-1 cross-coupled with a comb-like coil 90-1, each having one or multiple layers 52 or 92.

In the depicted embodiment, a first layer 52-1 of a first comb-like coil 50-1 and a first layer 52-1 of a second comb-like coil 50-2 is shown. For example, the first layers 52-1 of the comb-like coils 50-1 and 50-2 may be disposed adjacently on a single plane surface or across multiple plane surfaces. In different embodiments, the comb-like coils 50-1 and 50-2 may each have a different number of layers 52, for example, overlaid across multiple plane surfaces. Moreover, in the depicted embodiment, the traces 54-1 and 54-2 of the comb-like coils 50-1 and 50-2 may each have an octagonal shape. In different embodiments, the comb-like coils 50-1 and 50-2 may each have non-overlapping circular or polygonal shapes (e.g., or overlapping or intertwined circular or polygonal shapes) with different number of sides and/or side lengths.

The comb-like coils 50-1 and 50-2 may be cross-coupled, or coupled in parallel, by coupling the first terminals 56-1 and 56-2 to each other and coupling the second terminals 58-1 and 58-2 to each other. The first terminals 56-1 and 56-2 may be coupled by a first connector 152 and the second terminals 58-1 and 58-2 may be coupled by a second connector 154. As such, the first filter 150 may direct signals through the comb-like coils 50-1 and 50-2. For example, an input terminal (e.g., the terminals 56-1, 56-2, 58-1, or 58-2) and an output terminal (e.g., the terminals 56-1, 56-2, 58-1, or 58-2) of the first filter 150 may couple to one or more components of the electronic device 10 of FIGS. 1-5. Accordingly, during an operation of the electronic device 10, the comb-like coils 50-1 and 50-2 may receive and direct the signals through the traces 54-1 and 54-2.

In some cases, the comb-like coils 50-1 and 50-2 may be cross-coupled such that the first filter 150 may direct the signals in opposite directions. For example, the first comb-like coil 50-1 may direct an electrical current of the signals in clockwise (or counterclockwise) direction and the second comb-like coil 50-2 may direct the electrical current of the signals in counterclockwise (or clockwise) direction. As such, the cross-coupled comb-like coils 50-1 and 50-2 may have electromagnetic emissions in an opposite (e.g., nearly opposite) direction when receiving the signals. Accordingly, the first filter 150 may have a reduced electromagnetic emission compared to other filters based on the opposite (e.g., nearly opposite) direction of the electromagnetic emissions.

The first comb-like coil 50-1 may have a first resonating frequency range and the second comb-like coil 50-2 may have a second resonating frequency range. A resonating frequency range of the first filter 150 may correspond to a combination of the first resonating frequency range of the first comb-like coil 50-1 and the second resonating frequency range of the second comb-like coil 50-2. That is, the first filter 150 may conduct signals with frequencies within the first and second resonating frequency ranges and attenuate signals with frequencies outside the first and second resonating frequency ranges.

In some embodiments, the comb-like coils 50-1 and 50-2 may have different resonating frequency ranges. For example, the first and second resonating frequency ranges may be non-equal with overlapping or non-overlapping portions. As such, the first filter 150 may conduct the signals with frequencies within a wider resonating frequency range compared to the first resonating frequency range and the second resonating frequency range. Accordingly, the first filter 150 may have an increased resonating frequency range based on including two cross-coupled comb-like coils 50-1 and 50-2.

In some cases, the first filter 150 may provide a lower resistance and/or inductance to signals with frequencies within the first and/or second resonating frequency ranges compared to other filters. For example, the comb-like coils 50-1 and 50-2 may mutually (e.g., reciprocally) improve conductance of the first filter 150 with respect to signals with frequencies within the first and/or second resonating frequency ranges. Alternatively or additionally, the first filter 150 may provide a higher resistance and/or inductance to signals with frequencies outside the first and second resonating frequency ranges compared to other filters. For example, the comb-like coils 50-1 and 50-2 may mutually (e.g., reciprocally) improve resistance of the first filter 150 with respect to signals with frequencies outside the first and/or second resonating frequency ranges. As such, the first filter 150 may have improved efficiency and signal quality compared to other filters.

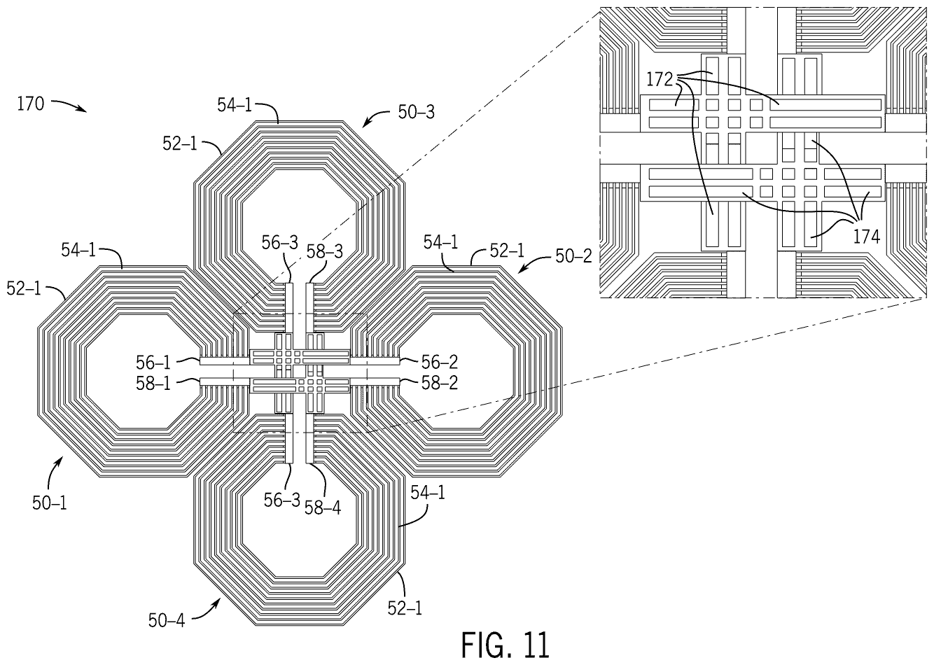

FIG. 11 illustrates the second filter 170 of the electronic device 10 of FIGS. 1-5 including four cross-coupled comb-like coils 50-1, 50-2, 50-3, and 50-4 of FIGS. 6 and 7, according to embodiments of the present disclosure. Although a first layer 52-1 of the comb-like coils 50-1, 50-2, 50-3, and 50-4 is shown, it should be appreciated that in alternative or additional embodiments, the comb-like coil 50-1, 50-2, 50-3, and/or 50-4 may include a different number (e.g., N, 2, 3, 4, and so on) of layers 52, as described above with respect to FIG. 7. Moreover, as mentioned above, it should be appreciated that in alternative or additional embodiments, the second filter 170 may include one or more cross-coupled comb-like coils 90 FIGS. 8 and/or 9 instead of one or more of the comb-like coils 50-1, 50-2, 50-3, and 50-4.

In the depicted embodiment, a first layer 52-1 of a first comb-like coil 50-1, a first layer 52-1 of a second comb-like coil 50-2, a first layer 52-1 of a third comb-like coil 50-3, and a first layer 52-1 of a fourth comb-like coil 50-4 is shown. For example, the first layers 52-1 of the comb-like coils 50-1, 50-2, 50-3, and 50-4 may be disposed adjacently on a single plane surface or across multiple plane surfaces. It should be appreciated that in different embodiments, the comb-like coils 50-1, 50-2, 50-3, and 50-4 may each have a different number of layers 52, for example, overlaid across multiple plane surfaces. Moreover, in the depicted embodiment, the traces 54-1, 54-2, 54-3, and 54-4 of the comb-like coils 50-1, 50-2, 50-3, and 50-4 may each have an octagonal shape. It should be appreciated that in different embodiments, the comb-like coils 50-1, 50-2, 50-3, and 50-4 may each have non-overlapping circular or polygonal shapes (e.g., or overlapping or intertwined circular or polygonal shapes) with different number of sides and/or side lengths.

The comb-like coils 50-1, 50-2, 50-3, and 50-4 may be cross-coupled, or coupled in parallel, by coupling the first terminals 56-1, 56-2, 56-3, and 56-4 to each other and coupling the second terminals 58-1, 58-2, 58-3, and 58-4 to each other. The first terminals 56-1, 56-2, 56-3, and 56-4 may be coupled by a first connector 172 and the second terminals 58-1, 58-2, 58-3, and 58-4 may be coupled by a second connector 174. As such, the second filter 170 may direct signals through the comb-like coils 50-1, 50-2, 50-3, and 50-4. For example, an input terminal (e.g., the first connector 172 or the terminals 56-1, 56-2, 56-3, 56-4, 58-1, 58-2, 58-3, or 58-4) and an output terminal (e.g., the second connector 174 or the terminals 56-1, 56-2, 56-3, 56-4, 58-1, 58-2, 58-3, or 58-4) of the second filter 170 may couple to one or more components of the electronic device 10 of FIGS. 1-5. Accordingly, during an operation of the electronic device 10, the comb-like coils 50-1, 50-2, 50-3, and 50-4 may receive and direct the signals through the traces 54-1, 54-2, 54-3, and 54-4.

In some cases, the comb-like coils 50-1, 50-2, 50-3, and 50-4 may be cross-coupled such that the second filter 170 may direct the signals in opposite directions. For example, the first comb-like coil 50-1 may direct the electrical current of the signals in clockwise (or counterclockwise) direction and the second comb-like coil 50-2 may direct the electrical current of the signals in counterclockwise (or clockwise) direction. As such, the cross-coupled comb-like coils 50-1 and 50-2 may have electromagnetic emissions in an opposite (e.g., nearly opposite) direction when receiving the signals. Moreover, the third comb-like coil 50-3 may direct the electrical current of the signals in clockwise (or counterclockwise) direction and the fourth comb-like coil 50-4 may direct the electrical current of the signals in counterclockwise (or clockwise) direction. As such, the cross-coupled comb-like coils 50-3 and 50-4 may have electromagnetic emissions in an opposite (e.g., nearly opposite) direction when receiving the signals. Accordingly, the second filter 170 may have a reduced electromagnetic emission compared to other filters based on the opposite (e.g., nearly opposite) direction of the electromagnetic emissions.

In some embodiments, the first comb-like coil 50-1 may have a first resonating frequency range, the second comb-like coil 50-2 may have a second resonating frequency range, the third comb-like coil 50-3 may have a third resonating frequency range, and the fourth comb-like coil 50-4 may have a fourth resonating frequency range. A resonating frequency range of the second filter 170 may correspond to a combination of the resonating frequency ranges of the comb-like coils 50-1, 50-2, 50-3, and 50-4. That is, the second filter 170 may conduct signals with frequencies within the first, second, third, and fourth resonating frequency ranges and attenuate signals with frequencies outside the first, second, third, and fourth resonating frequency ranges.

In such embodiments, the comb-like coils 50-1, 50-2, 50-3, and 50-4 may have different resonating frequency ranges. For example, either of the first, second, third, and/or fourth resonating frequency ranges may be non-equal with overlapping or non-overlapping portions. As such, the second filter 170 may conduct the signals with frequencies within a wider resonating frequency range compared to the resonating frequency range of either of the comb-like coils 50-1, 50-2, 50-3, and 50-4. Accordingly, the second filter 170 may have an increased resonating frequency range based on including four cross-coupled comb-like coils 50-1, 50-2, 50-3, and 50-4.

In some cases, the second filter 170 may provide a lower resistance and/or inductance to signals with frequencies within first, second, third, and/or fourth resonating frequency ranges compared to other filters. For example, the comb-like coils 50-1, 50-2, 50-3, and 50-4 may mutually (e.g., reciprocally) improve conductance of the second filter 170 with respect to signals with frequencies within the first, second, third, and/or fourth resonating frequency ranges. Alternatively or additionally, the second filter 170 may provide a higher resistance and/or inductance to signals with frequencies outside the first, second, third, and/or fourth resonating frequency ranges compared to other filters. For example, the comb-like coils 50-1, 50-2, 50-3, and 50-4 may mutually (e.g., reciprocally) improve resistance of the second filter 170 with respect to signals with frequencies outside the first, second, third, and/or fourth resonating frequency ranges. As such, the second filter 170 may have improved efficiency and signal quality compared to other filters.

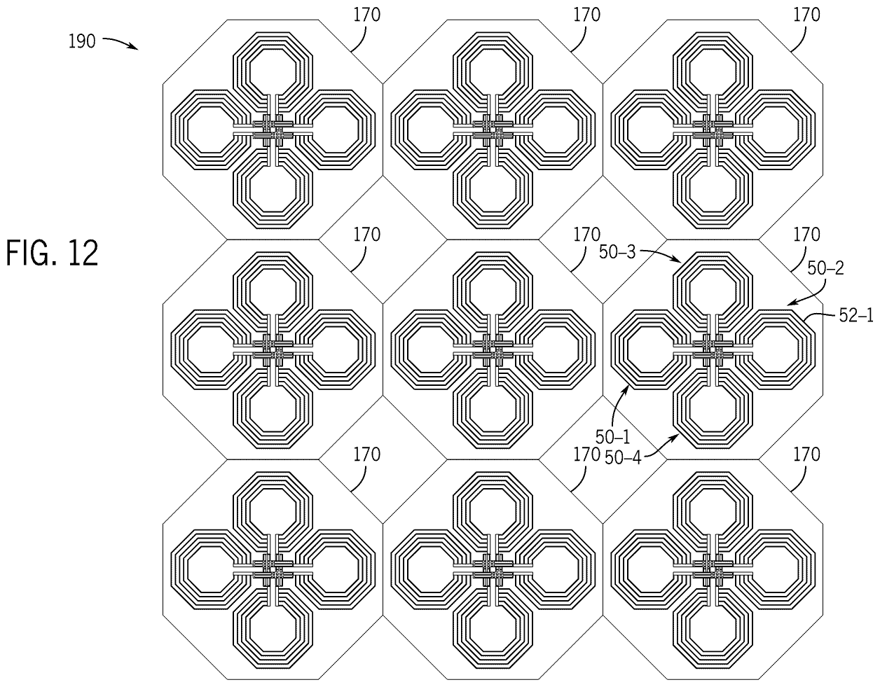

FIG. 12 illustrates the third filter 190 of the electronic device 10 of FIGS. 1-5 including multiple first filters 150 of FIG. 10 and/or second filters 170 of FIG. 11, according to embodiments of the present disclosure. In the depicted embodiment, the third filter 190 may include multiple cells of the four cross-coupled comb-like coils 50 forming the second filter 170. In alternative or additional embodiments, one or more of the cells of the third filter 190 may include the two cross-coupled comb-like coils 50 forming the first filter 150.

Moreover, although a first layer 52-1 of the comb-like coils 50-1, 50-2, 50-3, and 50-4 is shown, it should be appreciated that in alternative or additional embodiments, the comb-like coil 50-1, 50-2, 50-3, and/or 50-4 of one or more of the cells may include a different number (e.g., N, 2, 3, 4, and so on) of layers 52, as described above with respect to FIG. 7. Moreover, as mentioned above, it should be appreciated that in alternative or additional embodiments, the third filter 190 may include cross-coupled comb-like coils 90 FIGS. 8 and/or 9 instead of one or more of the comb-like coils 50-1, 50-2, 50-3, and 50-4 of the cells.

The cells of the third filter 190, each including the second filter 170 or the first filter 150, may be cross-coupled, or coupled in parallel, by coupling the first terminals 56 of each of the comb-like coils 50 to each other and coupling the second terminals 58 of each of the comb-like coils 50 to each other. As mentioned above, the first terminals 56 of each of the comb-like coils 50 of the second filter 170 (or the first filter 150) may be coupled by a first connector 172 (or a first connector 152) and the second terminals 58 of the second filter 170 (or the first filter 150) may be coupled by a second connector 174 (or a second connector 154). As such, the first connector 172 (or the first connector 152) of each of the cells may be coupled together. Moreover, the second connector 174 (or the second connector 154) of each of the cells may be coupled together.

In some cases, each of the cells of the third filter 190 may direct signals through the respective comb-like coils 50 simultaneously (e.g., nearly simultaneously). For example, an input terminal (e.g., a first connector 172 or 152 or a terminal 56 or 58) and an output terminal (e.g., the second connector 174 or 154 or a terminal 56 or 58) of one or multiple cells may couple to one or more components of the electronic device 10 of FIGS. 1-5. Accordingly, during an operation of the electronic device 10, the third filter 190 may receive and direct the signals through the cross-coupled comb-like coils 50 of each of the cells.

In some cases, the comb-like coils 50 of one or more of the cells may be cross-coupled to direct the signals in opposite directions. As such, the cross-coupled comb-like coils 50 of one or more of the cells may have electromagnetic emissions in an opposite (e.g., nearly opposite) direction when receiving signals. Accordingly, the third filter 190 may have a reduced electromagnetic emission compared to other filters based on the opposite (e.g., nearly opposite) direction of the electromagnetic emissions.

In some embodiments, the comb-like coils 50 of the cells may have different resonating frequency ranges. A resonating frequency range of the third filter 190 may correspond to a combination of the resonating frequency ranges of the comb-like coils 50 of each cell. That is, the third filter 190 may conduct signals with frequencies within the resonating frequency ranges of the comb-like coils 50 and attenuate signals with frequencies outside the resonating frequency ranges of the comb-like coils 50.

In such embodiments, the comb-like coils 50 of one or more cells and/or different cells may have different resonating frequency ranges. For example, the resonating frequency ranges of the comb-like coils 50 of one or more cells and/or different cells may be non-equal with overlapping or non-overlapping portions. As such, the third filter 190 may conduct the signals with frequencies within a wider resonating frequency range compared to the resonating frequency range of either of the comb-like coils 50 and/or cells including the second filter 170 (or the first filter 150). Accordingly, the third filter 190 may have an increased resonating frequency range based on including multiple cells of the second filter 170 (or the first filter 150).

In some cases, the third filter 190 may provide a lower resistance and/or inductance to signals with frequencies within resonating frequency ranges of at least a portion of the comb-like coils 50 of the third filter 190 compared to other filters. For example, the comb-like coils 50 and/or cells of the second filter 170 (or the first filter 150) may mutually (e.g., reciprocally) improve conductance of the third filter 190 with respect to signals with frequencies within the resonating frequency ranges of at least a portion of the comb-like coils 50 of the third filter 190. Alternatively or additionally, the third filter 190 may provide a higher resistance and/or inductance to signals with frequencies outside the resonating frequency ranges of at least a portion of the comb-like coils 50 and/or cells of the second filter 170 (or the first filter 150) compared to other filters. For example, the comb-like coils 50 may mutually (e.g., reciprocally) improve resistance of the third filter 190 with respect to signals with frequencies outside the resonating frequency ranges of at least a portion of the comb-like coils 50 and/or cells of the second filter 170 (or the first filter 150). As such, the third filter 190 may have improved efficiency and signal quality compared to other filters.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. A filter comprising:
a first terminal configured to receive signals;
a second terminal configured to output the signals, as filtered by a first comb-like coil and a second comb-like coil, having frequencies equal to or within a first resonating frequency range and a second resonating frequency range;
the first comb-like coil coupled to the first terminal and the second terminal, wherein the first comb-like coil is configured to conduct a portion of the signals having frequencies equal to or within the first resonating frequency range; and
the second comb-like coil coupled to the first terminal and the second terminal, wherein the second comb-like coil is configured to conduct a portion of the signals having frequencies equal to or within the second resonating frequency range.

2. The filter of claim 1, wherein the first comb-like coil and the second comb-like coil are configured to filter the signals by attenuating at least a portion of the signals having frequencies outside the first resonating frequency range and the second resonating frequency range.

3. The filter of claim 1, wherein the first comb-like coil is configured to conduct the portion of the signals having frequencies equal to or within the first resonating frequency range in a clockwise direction, and the second comb-like coil is configured to conduct the portion of the signals having frequencies equal to or within the second resonating frequency range in a counterclockwise direction.

4. The filter of claim 1, wherein the first comb-like coil comprises a plurality of traces, wherein a first trace and a second trace disposed adjacently are coupled to the first terminal and the second terminal, respectively.

5. The filter of claim 4, wherein the first trace and the second trace are configured to capacitively couple and conduct at least a portion of the signals having frequencies equal to or within the first resonating frequency range.

6. The filter of claim 1, comprising a third comb-like coil and a fourth comb-like coil coupled to the first terminal and the second terminal, wherein the third comb-like coil and the fourth comb-like coil are configured to conduct a portion of the signals having frequencies equal to or within at least a portion of the first resonating frequency range and the second resonating frequency range.

7. The filter of claim 1, comprising a plurality of cells, wherein a first cell of the plurality of cells comprises the first terminal, the second terminal, the first comb-like coil, and the second comb-like coil, and a second cell of the plurality of cells comprises:
a third terminal coupled to the first terminal;
a fourth terminal coupled to the second terminal;
a third comb-like coil coupled to the third terminal and the fourth terminal; and
a fourth comb-like coil coupled to the third terminal and the fourth terminal.

8. The filter of claim 7, wherein the third comb-like coil and the fourth comb-like coil are configured to conduct a portion of the signals having frequencies equal to or within at least a portion of the first resonating frequency range and the second resonating frequency range.

9. The filter of claim 7, wherein the second cell comprises a fifth comb-like coil and a sixth comb-like coil coupled to the third terminal and the fourth terminal.

10. A filter comprising:
a first comb-like coil, wherein the first comb-like coil is configured to conduct a first portion of received signals having frequencies equal to or within a first resonating frequency range in a clockwise direction; and
a second comb-like coil cross-coupled to the first comb-like coil, wherein the second comb-like coil is configured to conduct a second portion of the received signals having frequencies equal to or within a second resonating frequency range in a counterclockwise direction, wherein the filter is configured to conduct the first portion and the second portion of the received signals having frequencies equal to or within the first resonating frequency range and the second resonating frequency range.

11. The filter of claim 10, wherein the first comb-like coil and the second comb-like coil are configured to attenuate at least a portion of signals having frequencies outside the first resonating frequency range and the second resonating frequency range.

12. The filter of claim 10, wherein the first comb-like coil comprises a first plurality of layers, and the second comb-like coil comprises a second plurality of layers.

13. The filter of claim 12, wherein adjacent traces of each layer of the first plurality of layers or adjacent traces across neighboring layers are configured to capacitively couple and conduct the first portion of the received signals.

14. The filter of claim 10, comprising a third comb-like coil and a fourth comb-like coil cross-coupled to the first comb-like coil and the second comb-like coil.

15. A filter comprising:
a first comb-like coil comprising a first plurality of layers, wherein each layer of the first plurality of layers comprises a respective plurality of traces, wherein adjacent traces of each layer of the first plurality of layers are coupled to different terminals of the filter; and
a second comb-like coil cross-coupled to the first comb-like coil, wherein the second comb-like coil comprises a second plurality of layers, wherein each layer of the second plurality of layers comprises a respective plurality of traces, wherein adjacent traces of each layer of the second plurality of layers are coupled to the different terminals.

16. The filter of claim 15, wherein the first comb-like coil is configured to conduct one or more signals having frequencies equal to or within a first resonating frequency range.

17. The filter of claim 15, wherein the second comb-like coil is configured to conduct one or more signals having frequencies equal to or within a second resonating frequency.

18. The filter of claim 15, wherein the first comb-like coil and the second comb-like coil are configured to output at least a portion of received signals having frequencies equal to or within a first resonating frequency range and a second resonating frequency range.

19. The filter of claim 15, wherein adjacent traces of each layer of the first plurality of layers or adjacent traces across neighboring layers are configured to capacitively couple and conduct one or more signals having frequencies equal to or within a first resonating frequency range.

20. The filter of claim 15, comprising a third comb-like coil and a fourth comb-like coil cross-coupled to the first comb-like coil and the second comb-like coil.
